(19) United States
(12) Patent Application Publication
(10) Pub. No.: US 2021/0376186 A1
(43) Pub. Date: Dec. 2, 2021

(54) DIODE STRUCTURE AND METHOD OF FABRICATING THE SAME

(71) Applicants: Jiangsu Advanced Memory Technology Co., Ltd., Jiangsu (CN); Jiangsu Advanced Memory Semiconductor Co., Ltd., Jiangsu (CN)

(72) Inventors: Kuo-Feng LO, Hsinchu County (TW); Chung-Hon LAM, Hsinchu County (TW); Cheng-En WU, Hsinchu County (TW); Yu ZHU, Hsinchu County (TW); HAOREN ZHUANG, Hsinchu County (TW); Yen-Yu HSU, Hsinchu County (TW)

(21) Appl. No.: 16/931,464

(22) Filed: Jul. 17, 2020

(30) Foreign Application Priority Data
May 27, 2020 (CN) 202010459141.5

(51) Int. Cl. H01L 33/00; H01L 33/40; H01L 33/38

(52) U.S. Cl. CPC H01L 33/0037; H01L 33/385; H01L 33/40

(57) ABSTRACT

A diode structure includes a substrate, a pillar stack disposed on the substrate, and a first barrier layer. The pillar stack includes a first semiconductor layer, a silicon layer, and a second semiconductor layer, in which the first and second semiconductor layers respectively have different dopants such that a conductivity of the first semiconductor layer is different from a conductivity of the second semiconductor layer. The first barrier layer is disposed between the first semiconductor layer and the silicon layer, in which the first barrier layer is configured to prevent the dopants in the first semiconductor layer from diffusing into the silicon layer.

### RELATED APPLICATIONS

This application claims priority to Chinese Application Serial Number 202010459141.5, filed May 27, 2020, which is herein incorporated by reference.

### BACKGROUND

### Field of Invention

The present invention relates to a diode structure and a method of fabricating the same. More particularly, the present invention relates to a diode structure having a barrier layer and a method of fabricating the same.

### Description of Related Art

Diodes are conventional semiconductor devices and are widely utilized in electronic applications such as power circuits or voltage converters. Generally, a diode includes a first semiconductor layer, a second semiconductor layer, and other layers between the first and second semiconductor layers. The first and second semiconductor layers are doped with III group compounds or V group compounds such as n-type or p-type dopants to have conductivities. However, in the subsequent high-temperature process, the dopants would migrate and diffuse into neighbored layers because of thermal driving, thereby reducing the doping concentration of the doped regions.

Therefore, there is a need to provide a diode structure that is able to maintain the doping concentration of the doped regions.

### SUMMARY

According to some embodiments of the invention, a diode structure includes a substrate, a pillar stack disposed on the substrate, and a first barrier layer. The pillar stack includes a first semiconductor layer, a silicon layer, and a second semiconductor layer, in which the first and second semiconductor layers respectively have different dopants such that a conductivity of the first semiconductor layer is different from a conductivity of the second semiconductor layer. The first barrier layer is disposed between the first semiconductor layer and the silicon layer, in which the first barrier layer is configured to prevent the dopants in the first semiconductor layer from diffusing into the silicon layer.

According to some embodiments of the invention, a method of fabricating a diode structure includes providing a substrate; forming a stack on the substrate, and patterning the stack into a plurality of pillar stacks, in which the pillar stacks stand on the substrate. Forming the stack includes forming an electrode layer on the substrate; forming a first semiconductor layer on the electrode layer; and forming a first barrier layer on the first semiconductor layer.

According to some other embodiments of the invention, a method of fabricating a diode structure includes providing a substrate; forming a stack on the substrate, and patterning the stack into a plurality of pillar stacks, in which the pillar stacks stand on the substrate. Forming the stack includes forming an electrode layer on the substrate; forming a first semiconductor layer on the electrode layer; forming a first silicon layer on the first semiconductor layer; and forming a first barrier layer on the first silicon layer.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a flow chart of a method of fabricating a diode structure according to some embodiments of the invention;

FIG. 2 to FIG. 5 are cross-sectional views of the diode structure according to various stages of some embodiment of the method of the invention;

FIG. 6A to FIG. 6C are cross-sectional views of the diode structure according to various stages of another embodiments of the method of the invention;

FIG. 7A to FIG. 7C are cross-sectional views of the diode structure according to various stages of some embodiments of the method of the invention;

FIG. 8A to FIG. 8C are cross-sectional views of the diode structure according to various stages of some embodiments of the method of the invention; and

FIG. 9 to FIG. 11 are cross-sectional views of the diode structures according to different embodiments of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts. It will be understood that when an element is referred to as being “on” another element, it can be directly on the other element or intervening elements may be present therebetween. In contrast, when an element is referred to as being “directly on” another element, there are no intervening elements present.

As used herein, “around”, “about”, “substantially” or “approximately” shall generally mean within 20 percent, preferably within 10 percent, and more preferably within 5 percent of a given value or range. Numerical quantities given herein are approximate, meaning that the term “around”, “about”, “substantially” or “approximately” can be inferred if not expressly stated.

The present invention provides a diode structure having a first semiconductor layer, a second semiconductor layer, and a silicon layer between the first and second semiconductor layers. The first and second semiconductor layers are respectively doped with III group compounds or V group compounds to have opposite conductivities. A barrier layer is interposed between the first semiconductor layer and the silicon layer to prevent the dopants in the first semiconductor layer from diffusing into the silicon layer, so as to maintain the doping concentration and doping profile of the first semiconductor layer. Additionally, additional barrier layer can be interposed between the second semiconductor layer and the silicon layer to prevent the dopants in the second semiconductor layer from diffusing into the silicon layer, so as to maintain the doping concentration and doping profile of the second semiconductor layer.

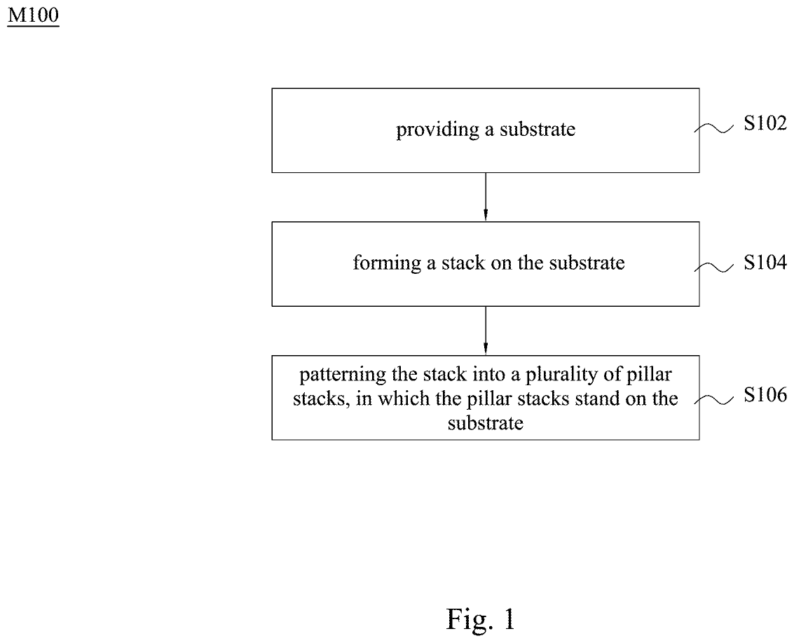

Referring to FIG. 1, FIG. 1 is a flow chart of a method M100 of fabricating a diode structure according to some embodiments of the invention. As shown in FIG. 1, the method M100 includes operations S102, S104, and S106.

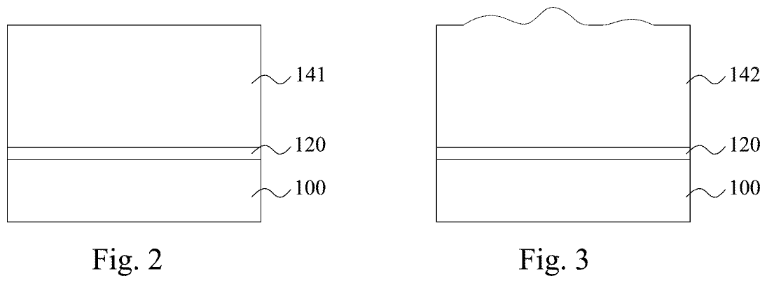

FIG. 2 to FIG. 5 are cross-sectional views of the diode structure according to various stages of some embodiment of the method M100.

Reference is made to operation S102 and FIG. 2, a substrate 100 is provided. In some embodiments, the substrate 100 can be a silicon substrate, a silicon-containing substrate, a III-V group compound on silicon substrate (e.g. GaN-on-silicon), or other semiconductor substrates.

As shown in FIG. 2, an electrode layer 120 is formed on the substrate 100. In some embodiments, the electrode layer 120 is deposited on the substrate 100. The material of the electrode layer 120 can be Au, Cr, Ni, Pt, Ti, Al, Ru, the combinations thereof, or other suitable conductive metal.

As shown in FIG. 3, after the electrode layer 120 is formed on the substrate 100, a first semiconductor layer 142 is formed on the electrode layer 120. In some embodiments, the first semiconductor layer 142 can be an n-type semiconductor layer. In some embodiments, the first semiconductor layer 142 can be an n-type polysilicon (poly-Si:n) layer.

In some embodiments, forming the n-type polysilicon layer includes, as illustrated in FIG. 2, forming a doped amorphous silicon layer 141 on the electrode layer 120, and crystalizing the doped amorphous silicon layer 141, such that the doped amorphous silicon layer 141 becomes the first semiconductor layer 142 in FIG. 3.

More particularly, an n-type amorphous silicon (a Si:n) layer is deposited on the electrode layer 120 by a chemical vapor deposition (CVD) process. Then an annealing process is performed to crystalize the deposited n-type amorphous silicon layer, such that the n-type amorphous silicon layer becomes the n-type polysilicon layer.

In some other embodiments, the n-type amorphous silicon layer is formed by an ion implantation process. For example, an amorphous silicon layer is formed on the electrode layer 120, and then an ion implantation process is performed to the amorphous silicon layer, thereby forming the doped amorphous silicon layer 141 in FIG. 2. A crystallization process is then performed to the doped amorphous silicon layer 141, such that the doped amorphous silicon layer 141 becomes the first semiconductor layer 142.

In some embodiments, the crystallization process includes an annealing process using such as, but not limit to, furnace anneal, rapid thermal anneal (RPT), laser annealing, forming gas annealing (FGA), or the likes.

In some embodiments, the first semiconductor layer 142 has a doping concentration ranging from 10¹⁷ atom/cm² to 10²¹ atom/cm². Preferably, the doping concentration of the first semiconductor layer 142 is from 10¹⁹ atom/cm² to 10²⁰ atom/cm².

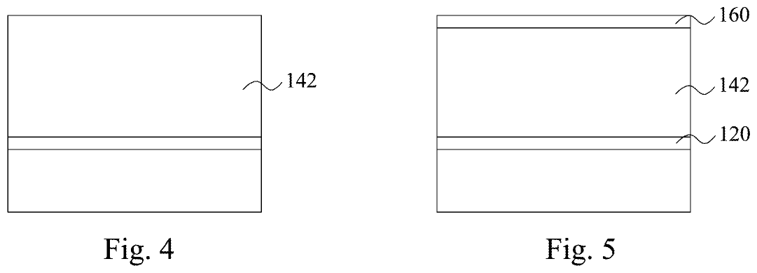

Reference is made to both FIG. 3 and FIG. 4. After the first semiconductor layer 142 is formed on the electrode layer 120, a planarization process is performed to the first semiconductor layer 142. Specifically, after the doped amorphous silicon layer 141 is crystalized to form the first semiconductor layer 142, the formed first semiconductor layer 142 generally has a rough or uneven surface. In some embodiments, a planarization process such as a CMP is performed to planarize the surface of the first semiconductor layer 142.

Referring to FIG. 5, a first barrier layer 160 is formed on the first semiconductor layer 142, after the first semiconductor layer 142 is formed on the electrode layer 120. In some embodiments, the first barrier layer 160 is made of conductive material. In some other embodiments, the first barrier layer 160 is made of graphene, Ni, W, Ti, TiN, PtSi, Mo, TiS₂, CoSi₂, NiSi, or NiPtSi. It is noted that graphene has better electric conductivity and thermal conductivity than conventional conductive materials. Therefore, the first barrier layer 160 made of graphene not only prevents dopant diffusion, but also is helpful in reducing resistance and increasing conductivity of the diode. Additionally, with the trend that density of the diodes on the chip is increased, the heat generated by the diodes is increased accordingly. Using graphene as the first barrier layer 160 is helpful in dissipating the heat generated by the diodes.

In some embodiments, the thickness of the first barrier layer 160 ranges from 10 Å to 50 Å. Preferably, the thickness of the first barrier layer 160 ranges from 10 Å to 20 Å, such as 12 Å, 14 Å, 16 Å, or 18 Å.

In some embodiments, the first barrier layer 160 is formed by chemical vapor deposition, organometallic chemical vapor deposition, physical vapor deposition, atomic layer deposition, pulsed laser deposition, evaporation, sputter, or any other suitable processes.

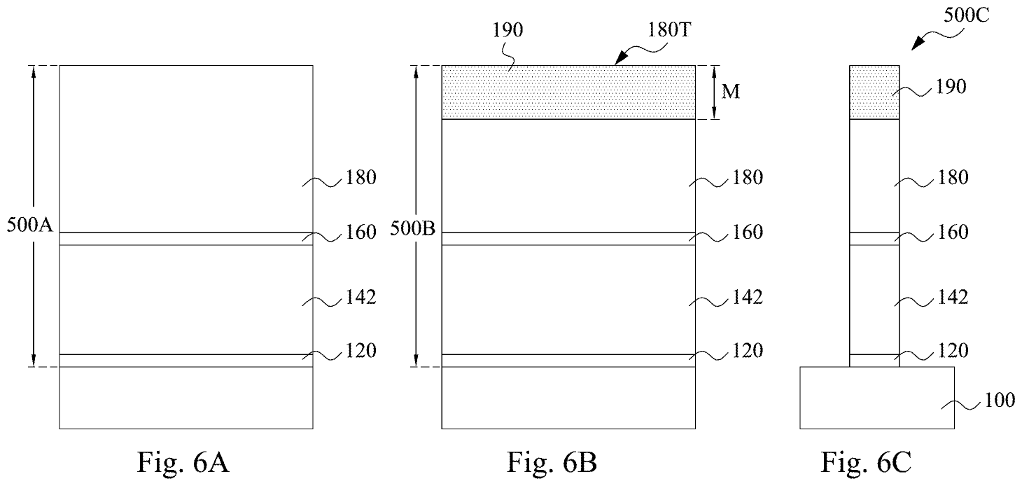

FIG. 6A to FIG. 6C are cross-sectional views of the diode structure according to various stages of some other embodiments of the method M100.

As shown in FIG. 6A, a first silicon layer 180 is formed on the first barrier layer 160 to form a stack 500A. In some embodiments, the first silicon layer 180 is an intrinsic silicon layer and is deposited on the first barrier layer 160. In some embodiments, the first silicon layer 180 is formed by chemical vapor deposition, plasma enhanced chemical vapor deposition, low-pressure chemical vapor deposition, or physical vapor deposition.

As shown in FIG. 6B, an ion implantation process is performed to the top surface 180T of the first silicon layer 180 to form a second semiconductor layer 190, in which the second semiconductor layer 190 extends from the top surface 180T of the first silicon layer 180 to the depth M.

In some embodiments, the second semiconductor layer 190 has a doping concentration ranging from 10¹⁷ atom/cm² to 10²¹ atom/cm². Preferably, the doping concentration of the second semiconductor layer 190 is from 10¹⁹ atom/cm² to 10²⁰ atom/cm².

In some embodiments, the second semiconductor layer 190 has conductivity opposite to that of the first semiconductor layer 142. For example, the first semiconductor layer 142 can be an N-type semiconductor layer, and the second semiconductor layer 190 can be a P-type semiconductor layer. Or, in some other embodiments, the first semiconductor layer 142 can be a P-type semiconductor layer, and the second semiconductor layer 190 can be an N-type semiconductor layer. The second semiconductor layer 190 and the first semiconductor layer 142 have opposite conductivities to form the diode.

In some embodiments, the first silicon layer 180 is lightly doped. In some embodiments, the doping concentration of the first silicon layer 180 is from 10¹⁴ atom/cm² to 10¹⁶ atom/cm². In some embodiments, the doping concentration of the first silicon layer 180 is lower than the doping concentration of the first semiconductor layer 142 or the second semiconductor layer 190.

Referring to operation S104, as shown in FIG. 6B, a stack 500B is formed on the substrate 100. Particularly, the stack 500B includes the electrode layer 120, the first semiconductor layer 142, the first barrier layer 160, the first silicon layer 180, and the second semiconductor layer 190.

Referring to operation S106 and FIG. 6C, the stack 500B is patterned to form a plurality of pillar stacks 500C, in which the pillar stacks 500C stand on the substrate 100. Each of the pillar stacks 500C, from the substrate 100, sequentially includes the electrode layer 120, the first semiconductor layer 142, the first barrier layer 160, the first silicon layer 180, and the second semiconductor layer 190.

More specifically, by using the patterning process such as one or more lithography and etching processes to pattern the stack 500B into the pillar stacks 500C. In some embodiments, patterning the stack 500B includes using one or more hard mask (not shown) in the etching process.

It is noted that the first barrier layer 160 is configured to prevent the dopants in the first semiconductor layer 142 from diffusing into the first silicon layer 180. More particularly, the first semiconductor layer 142 is doped to have a predetermined doping concentration and a predetermined doping profile, and a gradient of doping concentration is present in the first semiconductor layer 142. In the subsequent high temperature process such as a deposition process, the dopants may be driven by heat and diffuse from the first semiconductor layer 142 into the first silicon layer 180, thereby decreasing the doping concentration and changing the doping profile of the first semiconductor layer 142. The retention time of the diode structures is reduced accordingly.

According to some other aspects of the invention, additionally, a second barrier layer can be added into the diode structure and interpose between the second semiconductor layer 190 and the first silicon layer 180 to prevent the dopants in the second semiconductor layer 190 from diffusing into the first silicon layer 180.

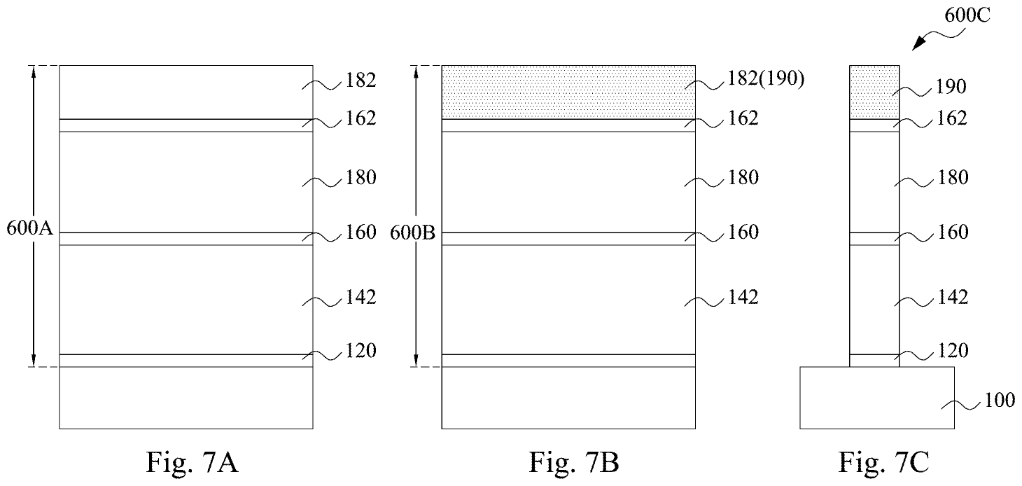

FIG. 7A to FIG. 7C are cross-sectional views of the diode structure according to various stages of some embodiments of the method M100.

According to some other aspect of the invention, as illustrated in FIG. 7A, a stack 600A is formed. The difference between FIG. 7A and FIG. 6A lies in that the stack 600A further includes a second barrier layer 162. More particularly, forming the stack 600A includes forming the first silicon layer 180 on the first barrier layer 160, forming the second barrier layer 162 on the first silicon layer 180, and forming a second silicon layer 182 on the second barrier layer 162. The step of forming the second silicon layer 182 is similar to that of forming the first silicon layer 180, and the step of forming the second barrier layer 162 is similar to that of forming the first barrier layer 160. Details thereof are not described herein again.

In some embodiments, the second barrier layer 162 is made of conductive material. In some other embodiments, the second barrier layer 162 is made of graphene, Ni, W, Ti, TiN, PtSi, Mo, TiS₂, CoSi₂, NiSi, or NiPtSi.

In some embodiments, the thickness of the second barrier layer 162 ranges from 10 Å to 50 Å. Preferably, the thickness of the second barrier layer 162 ranges from 10 Å to 20 Å, such as 12 Å, 14 Å, 16 Å, or 18 Å.

In some embodiments, the first barrier layer 160 and the second barrier layer 162 are made of the same or different materials. In some embodiments, the first barrier layer 160 and the second barrier layer 162 have substantially the same thickness.

Then, as shown in FIG. 7B, similar to FIG. 6B, an ion implantation process is performed to the second silicon layer 182, such that the second silicon layer 182 becomes the second semiconductor layer 190.

As shown in FIG. 7C, similar to FIG. 6C, the stack 600B is patterned to form a plurality of pillar stacks 600C, in which the pillar stacks 600C stand on the substrate 100. Each of the pillar stacks 600C, from the substrate 100, sequentially includes the electrode layer 120, the first semiconductor layer 142, the first barrier layer 160, the first silicon layer 180, the second barrier layer 162, and the second semiconductor layer 190.

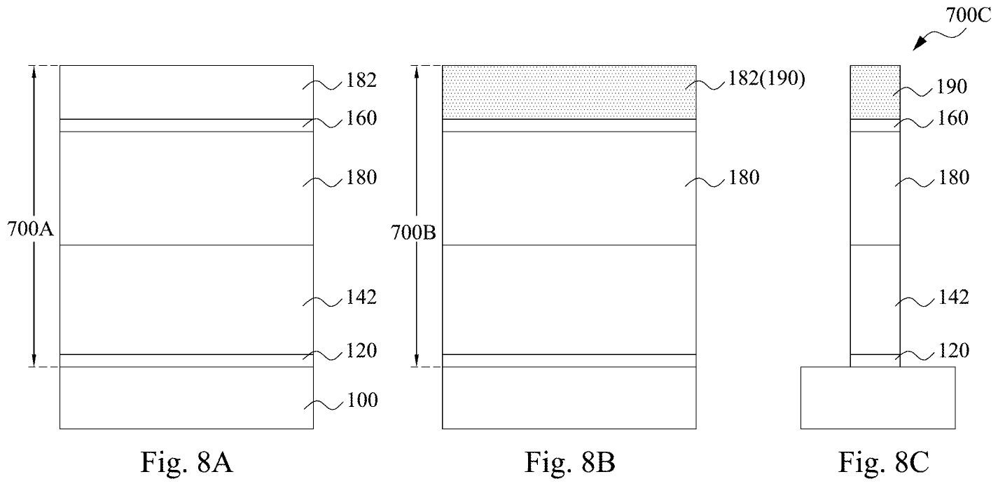

FIG. 8A to FIG. 8C are cross-sectional views of the diode structure according to various stages of some embodiments of the method of the invention.

According to yet some other embodiments of the invention, as illustrated in FIG. 8A, a stack 700A is formed. The difference between FIG. 8A and FIG. 6A lies in that the first barrier layer 160 of FIG. 8A is formed on the first silicon layer 180.

More particularly, as shown in FIG. 8A, forming the stack 700A includes forming the electrode layer 120 on the substrate 100, forming the first semiconductor layer 142 on the electrode layer 120, forming the first silicon layer 180 on first semiconductor layer 142, forming the first barrier layer 160 on the first silicon layer 180, and forming the second silicon layer 182 on the first barrier layer 160.

The steps of forming the electrode layer 120, the first semiconductor layer 142, the first silicon layer 180, and the first barrier layer 160 are similar to that as described in FIGS. 2-5. Details thereof are not described herein again. In some embodiments, a planarization step to the first semiconductor layer 142 is performed after forming the first semiconductor layer 142 and before forming the first silicon layer 180.

As shown in FIG. 8B, similar to FIG. 6B, an ion implantation process is performed to the second silicon layer 182, such that the second silicon layer 182 becomes the second semiconductor layer 190.

As shown in FIG. 8C, similar to FIG. 6C, the stack 700B is patterned to form a plurality of pillar stacks 700C, in which the pillar stacks 700C stand on the substrate 100. Each of the pillar stacks 700C, from the substrate 100, sequentially includes the electrode layer 120, the first semiconductor layer 142, the first silicon layer 180, the first barrier layer 160, and the second semiconductor layer 190.

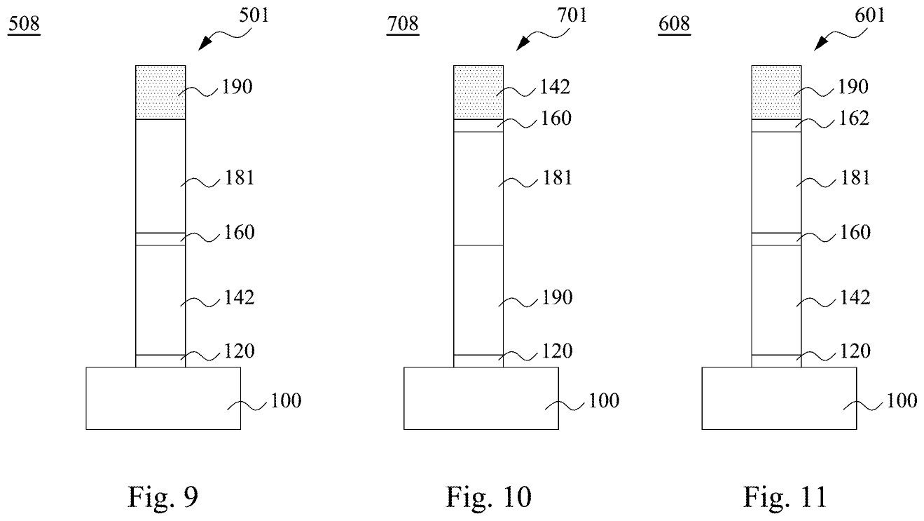

FIG. 9 to FIG. 11 are cross-sectional views of the diode structures 508, 608, 708, according to different embodiments of the invention.

As illustrated in FIG. 9, a diode structure 508 includes a substrate 100, a pillar stack 501, and a first barrier layer 160. The pillar stack 501 is disposed on the substrate 100. In some embodiments, the pillar stack 501 includes the first semiconductor layer 142, a silicon layer 181, and the second semiconductor layer 190. The first semiconductor layer 142 and the second semiconductor layer 190 are doped with different dopants to have opposite conductivities thereby forming a diode. The first barrier layer 160 is disposed between the first semiconductor layer 142 and the silicon layer 181. In some embodiments, the first barrier layer 160 is configured to prevent the dopants in the first semiconductor layer 142 from diffusing into the silicon layer 181.

In some embodiments, as shown in FIG. 9, the diode structure 508, from the substrate 100, sequentially includes the first semiconductor layer 142, the first barrier layer 160, the silicon layer 181, and the second semiconductor layer 190.

In some embodiments, as shown in FIG. 9, the diode structure 508 further includes the electrode layer 120. The electrode layer 120 is disposed between the first semiconductor layer 142 and the substrate 100.

In some embodiments, as shown in FIG. 10, the diode structure 708, from the substrate 100, sequentially includes the second semiconductor layer 190, the silicon layer 181, the first barrier layer 160, and the first semiconductor layer 142.

In some embodiments, as shown in FIG. 11, the diode structure 608 further includes the second barrier layer 162. The diode structure 608, from the substrate 100, sequentially includes the first semiconductor layer 142, the first barrier layer 160, the silicon layer 181, the second barrier layer 162, and the second semiconductor layer 190. The second barrier layer 162 is configured to prevent the dopants in the second semiconductor layer 190 from diffusing into the silicon layer 181.

Generally, the conventional barrier layer in the semiconductor technology is utilized to prevent pollution caused by diffusion between adjacent layers made of different materials (e.g. between the conductor and the dielectric layer). However, the barrier layer of the present invention is utilized to prevent pollution caused by dopant diffusion between adjacent layers made of substantially the same materials (e.g. both are silicon-based layers, in which one is doped and the other is undoped, or both are silicon-based layers but are doped with different dopants), such that the problem of diffusion between the semiconductor layer and the silicon layer is solved, and thus the decreasing of the doping concentration of the semiconductor layer, the changing of the doping profile of the semiconductor layer, and the decreasing of the retention time of the diode can be prevented. Therefore, the barrier layer of the invention has different position and different function than that of the conventional barrier layer. In addition, the barrier layer of the invention can be graphene, which can not only prevent dopant diffusion, but also is helpful in increasing conductivity of the diode. The barrier layer made of graphene can dissipate the heat generated by the diode efficiently.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A diode structure, comprising:
a substrate;
a pillar stack disposed on the substrate, the pillar stack comprising a first semiconductor layer, a silicon layer, and a second semiconductor layer, wherein the first and second semiconductor layers respectively have different dopants such that a conductivity of the first semiconductor layer is different from a conductivity of the second semiconductor layer; and
a first barrier layer disposed between the first semiconductor layer and the silicon layer, wherein the first barrier layer is configured to prevent the dopants in the first semiconductor layer from diffusing into the silicon layer.

2. The diode structure of claim 1, wherein the pillar stack, from the substrate, sequentially comprises the first semiconductor layer, the first barrier layer, the silicon layer, and the second semiconductor layer.

3. The diode structure of claim 1, wherein the pillar stack further comprises:
an electrode layer disposed between the first semiconductor layer and the substrate.

4. The diode structure of claim 1, wherein the pillar stack, from the substrate, sequentially comprises the second semiconductor layer, the silicon layer, the first barrier layer, and the first semiconductor layer.

5. The diode structure of claim 1, wherein the pillar stack further comprises a second barrier layer, the pillar stack, from the substrate, sequentially comprises the first semiconductor layer, the first barrier layer, the silicon layer, the second barrier layer, and the second semiconductor layer, and the second barrier layer is configured to prevent the dopants in the second semiconductor layer from diffusing into the silicon layer.

6. The diode structure of claim 5, wherein the second barrier layer comprises graphene, Ni, W, Ti, TiN, ptSi, Mo, TiS₂, CoSi₂, NiSi, or NiPtSi.

7. The diode structure of claim 1, wherein the first barrier layer is made of a conductive material.

8. The diode structure of claim 1, wherein the first barrier layer comprises graphene, Ni, W, Ti, TiN, ptSi, Mo, TiS₂, CoSi₂, NiSi, or NiPtSi.

9. The diode structure of claim 1, wherein a thickness of the first barrier layer ranges from 10 Å to 50 Å.

10. The diode structure of claim 1, wherein a doping concentration of the first semiconductor layer is from 10¹⁷ atom/cm² to 10²¹ atom/cm², and a doping concentration of the second semiconductor layer is from 10¹⁷ atom/cm² to 10²¹ atom/cm².

11. The diode structure of claim 1, wherein a doping concentration of the silicon layer is less than a doping concentration of the first semiconductor layer or the second semiconductor layer.

12. The diode structure of claim 1, wherein a doping concentration of the silicon layer is from 10¹⁴ atom/cm² to 10¹⁶ atom/cm².

13. A method of fabricating a diode structure, comprising:
providing a substrate;
forming a stack on the substrate, comprising:
forming an electrode layer on the substrate;
forming a first semiconductor layer on the electrode layer; and
forming a first barrier layer on the first semiconductor layer; and
patterning the stack into a plurality of pillar stacks, wherein the pillar stacks stand on the substrate.

14. The method of fabricating the diode structure of claim 13, wherein forming the stack on the substrate further comprises:
forming a first silicon layer on the first barrier layer after the first barrier layer is formed on the first semiconductor layer; and
performing an ion implantation process to a top surface of the first silicon layer, such that a second semiconductor layer is formed from the top surface of the first silicon layer to a depth,
wherein a conductivity of the first semiconductor layer is different from a conductivity of the second semiconductor layer, and
each of the pillar stacks, from the substrate, sequentially comprises the electrode layer, the first semiconductor layer, the first barrier layer, the first silicon layer, and the second semiconductor layer.

15. The method of fabricating the diode structure of claim 13, wherein forming the stack on the substrate further comprises:
forming a first silicon layer on the first barrier layer after the first barrier layer is formed on the first semiconductor layer;
forming a second barrier layer on the first silicon layer;
forming a second silicon layer on the second barrier layer; and
performing an ion implantation process to the second silicon layer, such that the second silicon layer is transformed into a second semiconductor layer,
wherein a conductivity of the first semiconductor layer is different from a conductivity of the second semiconductor layer, and
each of the pillar stacks, from the substrate, sequentially comprises the electrode layer, the first semiconductor layer, the first barrier layer, the first silicon layer, the second barrier layer, and the second semiconductor layer.

16. The method of fabricating the diode structure of claim 13, wherein forming the first semiconductor layer on the electrode layer comprises:
forming an amorphous silicon layer on the electrode layer;
performing an ion implantation process to the amorphous silicon layer, such that the amorphous silicon layer becomes a doped amorphous silicon layer;
crystalizing the doped amorphous silicon layer, such that the doped amorphous silicon layer becomes the first semiconductor layer; and
planarizing the first semiconductor layer.

17. The method of fabricating the diode structure of claim 13, wherein forming the first semiconductor layer on the electrode layer comprises:
forming a doped amorphous silicon layer on the electrode layer;
crystalizing the doped amorphous silicon layer, such that the doped amorphous silicon layer becomes the first semiconductor layer; and
planarizing the first semiconductor layer.

18. A method of fabricating a diode structure, comprising:
providing a substrate;
forming a stack on the substrate, comprising:
forming an electrode layer on the substrate;
forming a first semiconductor layer on the electrode layer;
forming a first silicon layer on the first semiconductor layer; and
forming a first barrier layer on the first silicon layer; and
patterning the stack into a plurality of pillar stacks, wherein the pillar stacks stand on the substrate.

19. The method of fabricating the diode structure of claim 18, wherein forming the stack on the substrate further comprises:
forming a second silicon layer on the first barrier layer after the first barrier layer is formed on the first silicon layer; and
performing an ion implantation process to the second silicon layer, such that the second silicon layer becomes a second semiconductor layer,
wherein a conductivity of the first semiconductor layer is different from a conductivity of the second semiconductor layer, and
each of the pillar stacks, from the substrate, sequentially comprises the electrode layer, the first semiconductor layer, the first silicon layer, the first barrier layer, and the second semiconductor layer.

20. The method of fabricating the diode structure of claim 18, further comprising:
planarizing the first semiconductor layer after the first semiconductor layer is formed on the electrode layer and before the first silicon layer is formed on the first semiconductor layer.
